(19) United States
(12) Patent Application Publication
(10) Pub. No.: US 2006/0176670 A1
(43) Pub. Date: Aug. 10, 2006

(54) Pedestal set

(75) Inventor: Kuan-Ting Chen, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/345,233

(22) Filed: Feb. 2, 2006

(30) Foreign Application Priority Data
Feb. 5, 2005 (TW) 094104113

(51) Int. Cl. H05K 7/20

(52) U.S. Cl. 361/704

(57) ABSTRACT

A pedestal set, which is used to bear an electronic device, the pedestal set includes a top plate and a bottom plate. The bottom plate is pivoted on the top plate.

### BACKGROUND OF THE INVENTION

1. Field of Invention

The invention relates to a pedestal set and, in particular, to a pedestal set used to a electronic product for setting vertically or horizontally.

2. Related Art

To avoid electronic products, such as desktop computers, scraping the tabletop or being fallen by an external force when they are placed on the table, elastic pedestals or pads made of rubber are disposed on the bottom of the electronic products for absorbing and decreasing the external force.

At present, the design of the pedestals or the pads is specific for the vertical or horizontal electronic products. In certain instances, users may set the electronic products vertically or horizontally due to space constraints. However, the pedestals or pads are not universal in both positions.

With reference to FIG. 1A, a vertical electronic product 10 has a pedestal 11 fastened to the bottom of the vertical electronic product 10. The pedestal 11 is not suitable to use when the user rotates the vertical electronic product 10 from the vertical position to the horizontal position. Therefore, due to the conventional design of the pedestal 11 is not flexible for suiting different spaces where the vertical electronic product 10 is placed, the operating space of the vertical electronic product 10 is dramatically limited. With reference to FIG. 1B, a horizontal electronic product 10′ has four rubber pads 12 fastened to the bottom of the horizontal electronic product 10′. When the user rotates the horizontal electronic product 10′ from the horizontal position to the vertical position, there is no pedestal or pad to provide support. Moreover, exposure of the pads 12 interferes with the look-and-feel of the horizontal electronic products 10′.

As mentioned above, due to the design of the conventional pedestal is specific for the vertical product or the horizontal product, it is a limitation for users to alter the position of the product. When the pedestal is not in use, the pedestal must be stored specially. That also causes users inconvenience.

Therefore, it is necessary to provide a pedestal set, which is universally used to vertical and horizontal electronic products as well as has an additional value.

### SUMMARY OF THE INVENTION

In view of the foregoing, the invention provides a pedestal set, which is universally used to vertical and horizontal electronic products.

To achieve the above, a pedestal set, which is used to a electronic product for setting vertically or horizontally, includes a top plate and a bottom plate. The bottom plate is pivoted on the top plate.

As mentioned above, the pedestal set is designed as an isolated element from the electronic device, so that the pedestal set can be used to the electronic device in the vertical position and in the horizontal position. Regardless of the electronic devices setting vertically or horizontally, the electronic devices can be disposed on the top plate of the pedestal set. Herein, the pedestal set assembled with the top plate and the bottom plate supports the electronic devices. In addition, the top plate and the bottom plate that are pivoted each other and can be rotated around a connecting shaft, respectively, so that an included angle can be formed between the top plate and the bottom plate. Hence, the lateral supporting force of the pedestal set can be reinforced and the electronic device would not be fallen or moved when an external force is exerted on the electronic device so as to stabilize the electronic device.

### BRIEF DESCRIPTION OF THE DRAWINGS

The invention will become more fully understood from the detailed description given herein below illustration only, and thus is not limitative of the present invention, and wherein:

FIG. 1A and FIG. 1B are schematic views showing the conventional electronic product with a pedestal or pads;

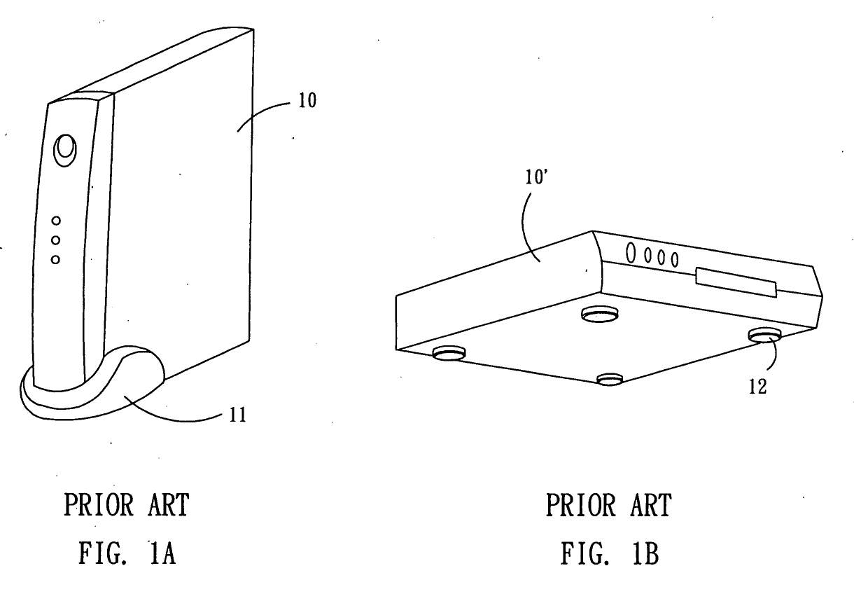

FIG. 2 is an exploded view showing the pedestal set according to a preferred embodiment of the invention;

FIG. 3A and FIG. 3B are schematic views showing the vertical electronic device and the horizontal electronic device disposed on the pedestal set according to the preferred embodiment of the invention; and

FIG. 4A and FIG. 4B are schematic views showing the pedestal set according to the preferred embodiment of the invention.

### DETAILED DESCRIPTION OF THE INVENTION

The present invention will be apparent from the following detailed description, which proceeds with reference, to the accompanying drawings, wherein the same references relate to the same elements.

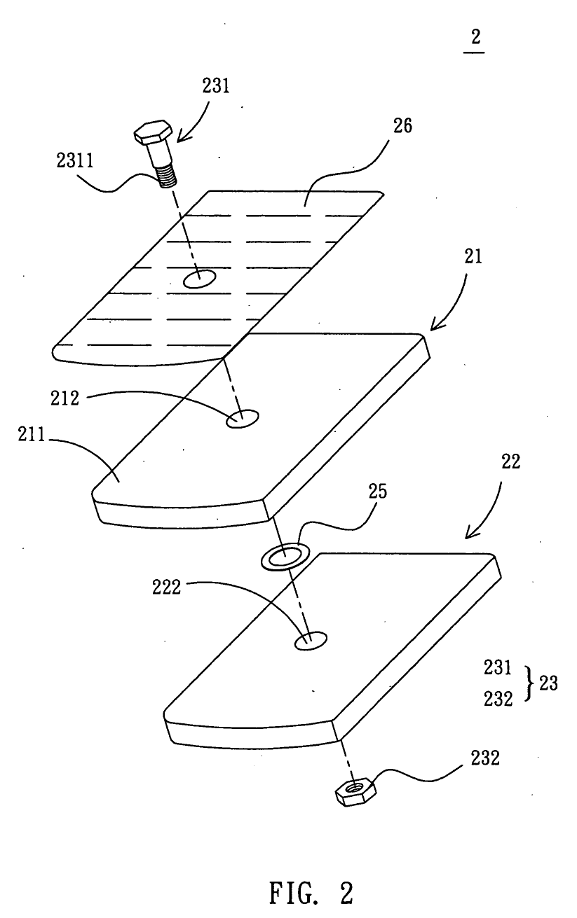

With reference to FIG. 2, the pedestal set 2 according to the embodiment of the invention includes a top plate 21, a bottom plate 22, and a connecting shaft 23.

In this case, the top plate 21 has a first surface 211 and a first through hole 212. The bottom plate 22 has a second through hole 222. In the present embodiment, the top plate 21 and the bottom plate 22 can be made of metal or a polymer material, such as plastic or rubber.

In the present embodiment, the connecting shaft 23, such as a screw set, passes through the first through hole 212 and the second through hole 222. One end of the connecting shaft 23 can be a screw 231 having a plurality of the threads 2311 to connect with a nut 232. Therefore, the pedestal set 2 is assembled by pivoting the top plate 21 on the bottom plate 22. Certainly, the connecting shaft 23 also can be a bar with blockers at both ends (not shown at FIG. 2).

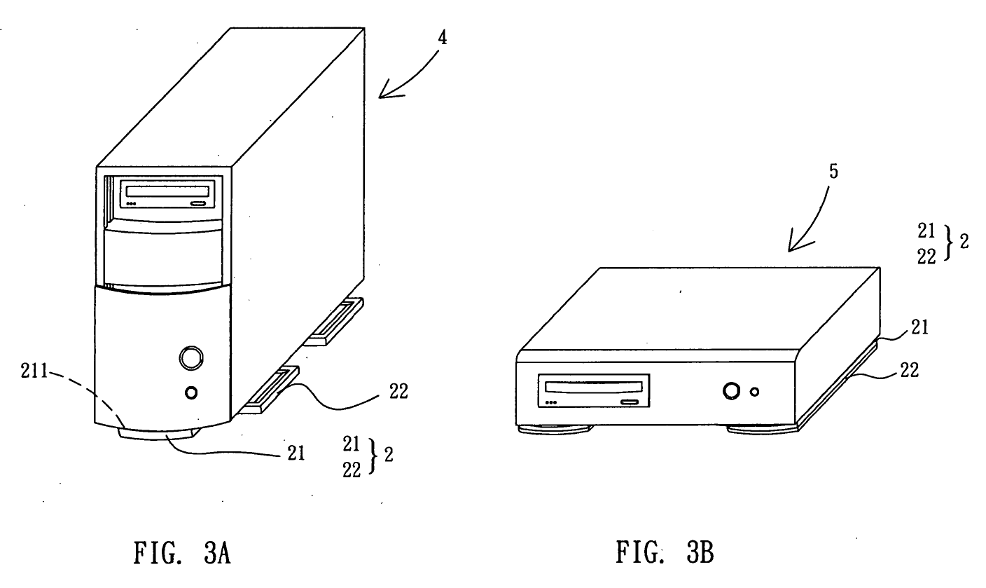

Additionally, with reference to FIG. 3A and FIG. 3B, the electronic device is disposed on the first surface 211 of the top plate 21. In this case, the electronic device can be a vertical electronic device 4 or a horizontal electronic device 5. In the present embodiment, in order to prevent the electronic device from sliding out of the pedestal set 2 by an external force, the first surface 211 of the top plate 21 can be covered by a rubber layer 26 with more friction or having effects on against sliding. Consequently, the friction of the first surface 211 is increased so that the electronic device can be stably disposed on the pedestal set 2 and does not slide randomly. When the electronic device is the vertical electronic device 4, its center of gravity is higher than that of the horizontal electronic device 5. Herein, the vertical electronic device 4 can be disposed on the top plate 21 after the top plate 21 and the bottom plate 22 of the pedestal set 2 being rotated about the connecting shaft 23, and an included angle is formed between the top plate 21 and the bottom plate 22 (as shown in FIG. 3A). Therefore, the pedestal set 2 can reinforce the lateral supporting force in such way so as to raise the stability of the vertical electronic device 4. On the other hand, if the electronic device is the horizontal electronic device 5, due to its center of gravity is lower than that of the vertical electronic device 4, the horizontal electronic device 5 is disposed on the top plate 21 after the top plate 21 and the bottom plate 22 of the pedestal set 2 being joined together (as shown in FIG. 3B). Of course, the use of the pedestal set 2 according to the embodiment of the invention is not limited to above description. It is flexible to modify the use of the pedestal set 2 according to the user's requirements.

In addition, with reference to FIG. 2, the pedestal set 2 further includes a buffer element 25, such as a pad, can be made of metal or a polymer material. The connecting shaft 23 passes through the buffer element 25 and the buffer element 25 is disposed between the top plate 21 and the bottom plate 22, so that the top plate 21 and the bottom plate 22 can be rotated about the connecting shaft 23 more easily.

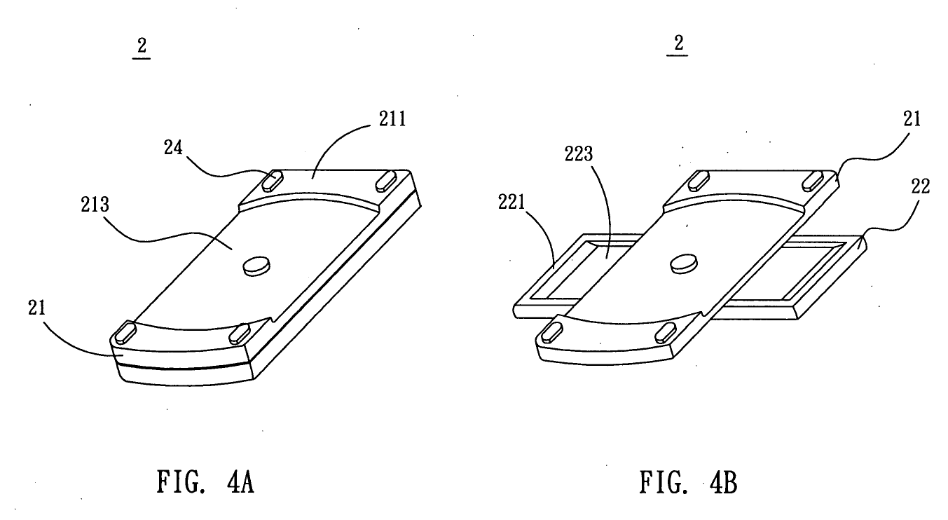

With reference to FIG. 4A, the top plate 21 of the pedestal set 2 has a first concave 213 formed on the first surface 211. When the pedestal set 2 is not in use, computer accessories, such as optical disc, can be placed in the first concave 213 that creates the additional value on the pedestal set 2. In addition, the top plate 21 further has at least one protruding portion 24 disposed on the first surface 211. Herein, the electronic device can have at least one concave portion on one surface of the electronic device, and the concave portion is opposite to the protruding portion 24 of the pedestal set 2. Therefore, in way of integrating the protruding portion 24 into the concave portion of the electronic device, the electronic device can more stably connect with the pedestal set 2. In the present embodiment, the protruding portion 24 can be made of the rubber.

In addition, with reference to FIG. 4B, the bottom plate 22 has a second surface 221 on which a second concave 223 is formed. When the top plate 21 and the bottom plate 22 are rotated to form the included angle between the top plate 21 and the bottom plate 22, the second concave 223 is exposed to provide a place where the stationery, such as paper clips or staples, can be put.

In conclusion, as mentioned above, the pedestal set is designed as an isolated element from the electronic device, so that the pedestal set can be used to the electronic device in the vertical position and in the horizontal position. Regardless of the vertical electronic devices or the horizontal electronic devices, the electronic devices can be disposed on the top plate of the pedestal set. Herein, the pedestal set assembled with the top plate and the bottom plate provides the supporting effect. In addition, the top plate and the bottom plate that are pivoted each other can be rotated about the connecting shaft 23, and then an included angle is formed between the top plate and the bottom plate. Hence, the lateral supporting force of the pedestal set can be reinforced and the electronic device would not be fallen or moved when an external force is exerted on the electronic device so as to further stabilize the electronic device. Moreover, when the pedestal set is not in use, the concaves formed on the surfaces of the top plate and the bottom plate can be designed as containers where the accessories, such as an optical disc, paper clips or staples, are placed. That is, the value of the pedestal set is increased so as to stimulate the customers to buy it.

Comparing with the conventional pedestal, the pedestal set of the invention has advantages as followings:

1. The pedestal set is an isolated element from the electronic device. So it can be used to the vertical electronic device and the horizontal electronic device.

2. The pedestal set has additional vales. When the pedestal set is not in use and is placed around the user, the concaves of top plate and the bottom plate are designed as containers to collect accessories like as an optical disc or staples.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A pedestal set, which is used to bear an electronic device, the pedestal set comprising:
a top plate; and
a bottom plate, which is pivoted on the top plate.

2. The pedestal set of claim 1, further comprising:
a connecting shaft, which passes through a first through hole of the top plate and a second through hole of the bottom plate, and connects the top plate and the bottom plate.

3. The pedestal set of claim 2, wherein the connecting shaft is assembled with a screw and a nut.

4. The pedestal set of claim 2, further comprising:
a buffer element, which passes through the connecting shaft and is disposed between the top plate and the bottom plate.

5. The pedestal set of claim 4, wherein the buffer element is a pad.

6. The pedestal set of claim 1, wherein the top plate has a first surface on which the electronic device is disposed, and the top plate has a first concave formed on the first surface.

7. The pedestal set of claim 6, further comprising:
a rubber layer, which covers the first surface of the top plate.

8. The pedestal set of claim 1, wherein the top plate has a first surface on which the electronic device is disposed, and the top plate further has at least one protruding portion disposed on the first surface.

9. The pedestal set of claim 8, wherein the protruding portion includes rubber.

10. The pedestal set of claim 1, wherein the bottom plate has a second surface facing the top plate and a second concave formed on the second surface.

11. The pedestal set of claim 1, wherein the top plate includes metal.

12. The pedestal set of claim 1, wherein the top plate includes a polymer material.

13. The pedestal set of claim 12, wherein the top plate includes plastic or rubber.

14. The pedestal set of claim 1, wherein the bottom plate includes metal.

15. The pedestal set of claim 1, wherein the bottom plate includes a polymer material.

16. The pedestal set of claim 15, wherein the bottom plate includes plastic or rubber.
